(19) United States
(12) Patent Application Publication
(10) Pub. No.: US 2002/0154045 A1
(43) Pub. Date: Oct. 24, 2002

(54) Method for adapting a decision level in the conversion of an analog signal into a digital signal, and digital receiver

(76) Inventor: Torsten Klemm, Eschborn (DE)

Correspondence Address: ERIC L. PRAHL, Fish & Richardson P.C., 225 Franklin Street, Boston, MA, 02110-2804, US

(21) Appl. No.: 10/167,879

(22) Filed: Jun. 12, 2002

Related U.S. Application Data
(63) Continuation of application No. PCT/EP01/00440, filed on Jan. 17, 2001.

(30) Foreign Application Priority Data
Feb. 19, 2000 (DE) 10007752.8

(51) Int. Cl. H03M 1/00

(52) U.S. Cl. 341/126

(57) ABSTRACT

The invention is directed to a method for adapting decision levels in the conversion of a multi-level analog signal into a digital signal, and to a digital receiver. As starting condition a certain level difference between two levels and also a first logic state, which the analog signal represents at the beginning of the data transmission, are predetermined. A second logic state is recognized in that the level of the analog signal varies by more than the level difference. A decision level is then calculated continually which lies between the levels of the first and second logic state.

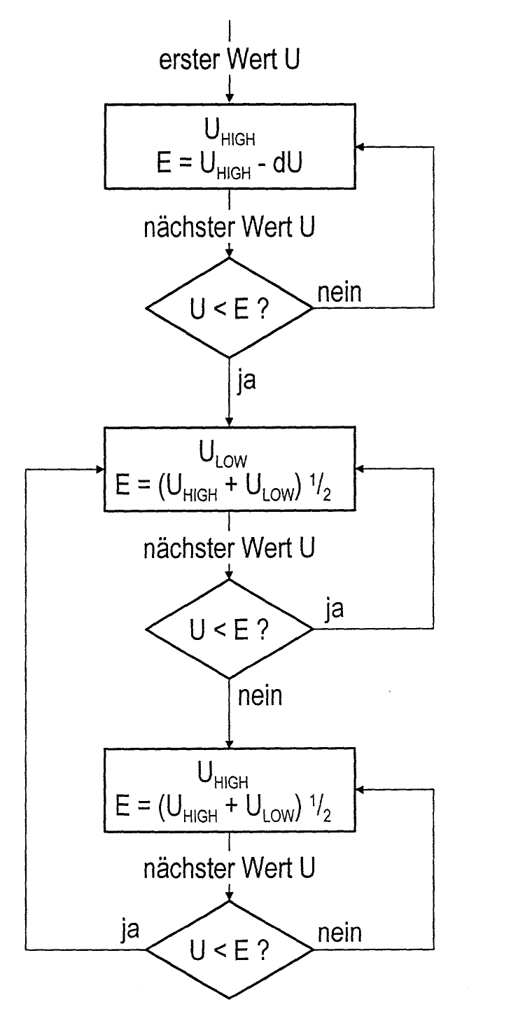

This invention relates to a method for adapting decision levels in the conversion of an analog signal into a digital signal, and to a digital receiver, being suitable in particular for an optical or inductive data transmission system with which an analog data signal is transmitted which is capable of representing at least two different logic states differing in their levels.

From EP 0 540 359 A2 there is known a digital detector for a four-level pulse-amplitude-modulated (4PAM) signal, which to differentiate between the four levels has a logic circuit with three decision levels, which it adapts to the output level of a receiving circuit connected up-stream from the detector in addition to performing a continual adaptation to fluctuating conditions of transmission. The algorithm used for this purpose is not disclosed. The 4PAM signal is digitized by an A/D converter, which requires the levels of the 4PAM signal to lie within the conversion range of the A/D converter to prevent overflow from occurring.

It is an object of the present invention to provide a simple method with which decision levels for the conversion of an analog data signal into a digital signal can be adapted during data transmission to fluctuating signal levels, as well as a digital receiver for implementing the method of the invention.

The method according to the invention is characterized in that it operates without preset values for the logic levels. There are, however, certain predetermined level differences between the individual levels as starting condition, along with a first predetermined logic state which the data signal represents at the beginning of the data transmission. A second logic state is recognized in that the level of the analog signal varies by more than the level difference. From the levels of the two logic states a decision level is calculated which lies between these levels. Once the levels of the first and second logic state and the decision level have been determined, these levels are continually adapted to the fluctuating conditions of transmission.

In a preferred variant of the method of the invention, the analog data signal is sampled in the digital receiver several times within a bit period and a logic level is formed from the average of the sampled values obtained during a bit period. At the beginning of data transmission the second logic state is recognized in that two successive averages of sampled values differ by more than the level difference. The decision level is then calculated from the levels of the first and second logic state, which are determined by averaging. The continual adaptation of the levels then takes place on the basis of the average values continually determined from the sampled values.

A digital receiver operating according to the method of the invention does not need to be set to the level of the respective transmission route because it adapts automatically. It includes, for example, an A/D converter, which continually samples and digitizes the analog data signal, as well as an arithmetic unit for the calculation of decision levels, and several registers for the storing of digitized sampled values and decision levels or level differences.

The method of the present invention will first be described for the case of only two logic levels, namely HIGH and LOW, needing to be recognized and differentiated in the analog data signal, which means that there is only one decision level needing to be adapted during the data transmission. It is assumed that no level outside the A/D range occurs during the data transmission.

In the following the level difference between LOW and HIGH preset as starting condition will be referred to as dU, and the logic state of the data signal at the beginning of the data transmission shall be HIGH, corresponding to the HIGH level U_{HIGH}.

In a first step the first sampled value U is saved as U_{HIGH}, and a decision level E=U_{HIGH}−dU is calculated and stored.

In a second step the second sampled value U is then compared with the stored decision level E. If the second sampled value U is greater than or equal to the stored decision level E, the second sampled value U will then be stored as U_{HIGH} and a new decision level E=U_{HIGH}−dU will be calculated and stored. If the subsequent sampled values are also greater than or equal to the last stored decision level E, the sampled values will be stored as U_{HIGH} and in each case the corresponding new decision level E=U_{HIGH}−dU will be calculated and stored. However, if either the second or one of the following sampled values U is smaller than the stored decision level E, the new sampled value U will then be stored as U_{LOW} and a new decision level E=½ (U_{HIGH}+U_{LOW} ) will be calculated and stored.

In all the subsequent steps the next sampled value U will be compared with the last stored decision level E and, if it is greater than or equal to the last stored decision level E it will be stored as U_{HIGH} or otherwise as U_{LOW}. In both cases a new decision level E=½ (U_{HIGH}+U_{LOW}) will be calculated and stored.

The above described procedure of the method of the invention is represented in the sole FIGURE, where the first value U or the next value U are to be understood as either sampled values or average values of sampled values.

If the starting condition of the logic state of the data signal at the beginning of the data transmission is to be LOW and not HIGH as described, with LOW level U_{LOW} correspondingly, in the first step the first sampled value U will then be stored as U_{LOW} and the decision level E=U_{LOW}+dU will be calculated and stored. Obviously, the next sequential steps will change accordingly.

The method of the invention is also suitable for adapting decision levels in the conversion of an analog signal with more than two levels into a digital signal. If the data transmission takes place with a three-level analog signal, for example, it is advantageous to select the middle logic level as starting condition and determine two level differences dU′ and dU″ with which, proceeding from the middle logic level, two decision levels E′ and E″ are calculated, lying respectively between the middle and the upper level and between the middle and the low logic level.

The difference between the HIGH level and the LOW level can be calculated and indicated as a criterion for the quality of transmission. A quantitatively large difference indicates high transmission reliability and vice versa. Furthermore, in the case of an optical transmission route a decision level that varies over time in relation to a reference level is evidence that the optical transmitter and/or receiver element is becoming increasingly soiled, which can also be indicated.

1. A method for adapting a decision level in the conversion of a multi-level analog signal into a digital signal, wherein as starting condition a certain level difference between two levels and also a first logic state, which the analog signal represents at the beginning of the data transmission, are predetermined, wherein a second logic state is recognized in that the level of the analog signal varies by more than the level difference, and wherein a decision level is then calculated which lies between the levels of the first and second logic state.

2. The method as claimed in claim 1, characterized by the steps of sampling the analog data signal several times within a bit period and calculating the levels of the logic states from the averages of the sampled values obtained during a bit period, and recognizing the second logic state in that two successive averages of sampled values differ by more than the level difference.

3. The method as claimed in claim 1 or 2, characterized by the steps of continually determining the levels of the first and second logic state and continually calculating therefrom a decision level which lies between the levels of the first and second logic state.

4. The method as claimed in claim 1, 2 or 3, characterized by the step of calculating the difference between the HIGH level and the LOW level as criterion for the quality of transmission.

5. The method as claimed in claim 3, characterized by the step of calculating the difference between the decision level and a reference level as criterion for a soiled optical transmitter and/or receiver element of an optical transmission route.

6. The method as claimed in claim 4 or 5, characterized by the step of indicating the transmission quality and/or the soiling.

7. A digital receiver for implementing the method according to any one of the preceding claims, characterized in that it includes an A/D converter for sampling and digitizing an analog signal as well as several registers for the storing of digitized sampled values.

8. The digital receiver as claimed in claim 7, characterized in that it further includes an arithmetic unit for the calculation of decision levels and averages of sampled values.

9. The digital receiver as claimed in claim 8, characterized in that the arithmetic unit further calculates as criterion for the transmission quality the difference between the HIGH level and the LOW level.

10. The digital receiver as claimed in claim 9 or 8, characterized in that the arithmetic unit further calculates as criterion for the soiling of an optical transmitter and/or receiver element the difference between the decision level and a reference level.

11. The digital receiver as claimed in claim 10 or 9, characterized in that it includes an indicating device for the transmission quality and/or the soiling.
